(19) United States
(12) Patent Application Publication
(10) Pub. No.: US 2026/0022201 A1
(43) Pub. Date: Jan. 22, 2026

(54) Polyurethanes, Polishing Articles and Polishing Systems Therefrom and Method of Use Thereof

(71) Applicant: 3M INNOVATIVE PROPERTIES COMPANY, Saint Paul, MN (US)

(72) Inventors: Joseph D. Rule, Woodbury, MN (US); David P. Siglin, St. Paul, MN (US); Jay M. Jennen, Forest Lake, MN (US); Jaimie E. Stomberg, Minneapolis, MN (US); Duy K. Lehuu, Lake Elmo, MN (US)

(21) Appl. No.: 18/997,254

(22) PCT Filed: Jul. 11, 2023
(86) PCT No.: PCT/IB2023/057119

§ 371 Date: Jan. 21, 2025

Related U.S. Application Data
(60) Provisional application No. 63/393,676, filed on Jul. 29, 2022.

(51) Int. Cl. C08G 18/60; B24B 37/24; C08G 18/28; C08G 18/32; C08G 18/40; C08G 18/42; C08G 18/66; C08G 18/76; H01L 21/321

(52) U.S. Cl. CPC C08G 18/603; B24B 37/24; C08G 18/2825; C08G 18/3206; C08G 18/4054; C08G 18/4238; C08G 18/664; C08G 18/7671; H01L 21/3212

(57) ABSTRACT

Polyurethanes and polishing articles made therefrom including a reaction product of a reactive mixture including a polyol, a diol chain extender, a diisocyanate, a mono-alcohol, and a multifunctional amine are described. The mole ratio of isocyanate groups to hydroxyl groups in the reactive mixture is 0.98 or greater. Such polyurethanes may remain stable even at extended exposure to elevated reactive extrusion temperatures.

### BACKGROUND

Polyurethane synthesis and film fabrication are described in, for example, U.S. Patent Publication 2020/0277517 and U.S. Pat. No. 10,590,303. Use of polyurethane films in polishing articles is described in, for example, U.S. Pat. Nos. 10,071,461 and 10,252,396.

### SUMMARY

In one aspect, the present description relates to a polyurethane including a reaction product of a reactive mixture including a polyol, a diol chain extender, a diisocyanate, a mono-alcohol, and a multifunctional amine. The mole ratio of isocyanate groups to hydroxyl groups in the reactive mixture is 0.98 or greater.

### BRIEF DESCRIPTION OF THE DRAWINGS

FIG. 1 is a schematic cross-sectional diagram of a portion of a polishing layer in accordance with some embodiments described herein.

FIG. 2 is a schematic cross-sectional diagram of a polishing pad in accordance with some embodiments described herein.

FIG. 3 illustrates a schematic diagram of an example of a polishing system for utilizing the polishing pads and methods in accordance with some embodiments described herein.

### DETAILED DESCRIPTION

Polyurethanes are versatile resins generally synthesized from mixtures of polyols and polyisocyanates. Polyols are organic compounds having at least two alcohol functional groups, and polyisocyanates are organic compounds having at least two isocyanate functional groups. In addition to these core components, other compounds may be added during synthesis, including but not limited to chain extenders, chain termination agents, crosslinkers, catalysts, and the like. Both thermoplastic and thermoset polyurethanes may be synthesized and, due to the extensive compounds that may be used in their synthesis, a wide range of material properties is achievable. Due at least to their general toughness, abrasion resistance, and chemical resistance, polyurethanes are often used in and as protective coatings and films.

One area where polyurethane films may be particularly useful is as abrasive materials for various polishing applications, for example, chemical mechanical planarization (CMP) polishing applications. In a typical CMP process, a surface of a substrate (for example, a semiconductor wafer), is contacted with a surface of a polishing pad. This contacting is often done in the presence of a working liquid or slurry. The substrate is moved relative to the pad under a specified force or pressure, causing the controlled removal of material from the substrate surface. The polishing pad often has multiple layers, including a polishing layer (that is, the layer of the pad that is designed to contact the substrate) and a subpad. The design of the polishing layer is important to the polishing performance. Some polishing layers may include a working surface (i.e., the surface intended to contact the substrate being polished) having specifically shaped or designed polishing features (for example, asperities and/or pores) that facilitate the polishing process. The height of the asperities and/or the depth of the pores, if included, are important parameters influencing the polishing pad's performance. For asperities, as an example, it may be advantageous to have the height of the tallest asperities to be uniform or substantially uniform, creating a planar surface of asperity tips. This allows the substrate surface to be uniformly contacted across the set of asperities. Additionally, the overall thickness of the polishing layer may be important to the polishing pad's performance. Generally, it may be advantageous for the polishing layer to have a uniform thickness to allow the working surface of the polishing layer to be planar. Thickness variations may translate into nonplanarity of the polishing layer working surface and affect polishing performance: the substrate may be contacted by only thicker regions of the polishing layer and not thinner regions elsewhere on the polishing layer. Additionally, any non-uniform thickness may also lead to non-uniform polishing pressure, which could adversely affect polishing results. The dimensional uniformity of the polishing layer thickness and/or polishing features being critical to the polish process may create demanding tolerance requirements, as the polishing layer in a film format may in some cases have a thickness of less than 1 mm and the corresponding polishing features may have dimensions (e.g., height or depth) of between 20 and 100 micrometers.

In addition to these dimensional requirements, the working fluids (for example, polishing solutions or slurries) may be corrosive (acidic, basic, and/or highly oxidizing), so the polishing layer may be configured or selected to provide good chemical resistance. Similarly, it may be important in certain applications for the polishing layer to last a sufficient length of time to meet the polishing life requirement of a given polishing process, so the polishing layer may be configured or selected to provide good abrasion resistance. Other potentially advantageous characteristics include the ability to produce in a low cost easily reproducible, and or high yield manufacturing process.

One method for creating polishing features on a working surface of a polishing layer is through the use of an embossing process. In this approach, a polishing layer may be prepared from a thermoplastic that is melt processed (via an extruder, for example) and cast onto an embossing roll and includes the negative image of the desired polishing layer features. In some embodiments, if the features are on the scale or have dimensions of about 500 micrometers or less, this process may be considered or called a microreplication process. The thermoplastic is then cooled on the embossing roll to cause solidification, followed by the removal of the thermoplastic film with embossed features from the roll. With respect to melt processing, the thermoplastic may be synthesized, pelletized, and then processed into film at a later time. However, greater efficiency may be achieved by making the thermoplastic in-situ, in an extruder through reactive extrusion. The polyurethane produced can then be formed into a film. In either case, stable fluid flow is required during the casting/embossing process to insure uniform film thickness and uniform feature sizes. Stable fluid flow during melt processing may correlate with stable melt viscosity of the thermoplastic at the melt process temperature, for example. Polyurethanes that are useful as a polishing layer of CMP pads may require high temperatures to form a melt, for example, temperatures between 180° C. and 250° C. Variations in viscosity or other properties of the urethane melt in this temperature range can lead to unacceptable coating defects. In addition, low viscosity of the polyurethane melt in this temperature range can lead to low pressures during the fabrication process, e.g., a casting/embossing microreplication process, which can in turn lead to poor replication fidelity. Therefore, urethane materials with high melt viscosity between 180° C. and 250° C. may be useful in some embodiments.

In addition to the above characteristics, the zeta potential of the polyurethanes of the present description may be important in some embodiments. For example, the zeta potential of a polyurethane used as the polishing layer of a CMP pad may influence the polishing behavior exhibited by the pad. Thus, the capability to modify, select, or influence the zeta potential of the polyurethane may lead to improved polishing performance. The zeta potential may be modified by blending compounds—typically lower molecular weight compounds—having various functional groups into the polyurethane. However, these compounds may be prone to migration and/or diffusion within the polyurethane and may not stay uniformly dispersed throughout the polyurethane. For example, during use of the polishing layer of a CMP pad, the polyurethanes may contact aqueous and/or non-aqueous polishing solutions that may be capable of extracting components from the polyurethane, particularly at the surface region of the polyurethane polishing layer. The components may then diffuse into the polishing solutions (that is, be removed from the polyurethane polishing layer), rending them ineffective as zeta potential modifiers.

Polyurethanes described herein may include multifunctional amines that are capable of reacting into the polyurethane backbone while modifying the zeta potential of the polyurethanes. Typically, these compounds increase the zeta potential of the polyurethanes and may provide a polyurethane with a positive zeta potential. As the multifunctional amines are, generally uniformly dispersed throughout the polyurethane and permanently included in the backbone due to covalent bonding, the zeta potential of the polyurethane is modified in a more stable fashion and may maintain a more consistent value during intended use. As the polyurethane wears during use, for example, during a CMP polishing process, fresh polyurethane will be exposed having a zeta potential substantially equivalent to the now-eroded surface. This behavior is distinguishable from materials that are incapable of reacting into the polyurethane itself during synthesis and/or are simply blended into a reacted polyurethane, as these materials may diffuse and phase separate within the polyurethane, bloom to the surface of the polyurethane, and/or be extracted from the polyurethane during use.

Unreacted end groups in the urethane copolymer may cause instability and inconsistency in the polyurethane, especially at elevated temperatures, such as during extrusion. The end groups can be controlled by the excess hydroxyl groups or amine groups relative to the isocyanate groups. Amines generally react with isocyanate more quickly than the hydroxyls react with the isocyanate. Therefore, in early stages of the reaction, amines may be disproportionately consumed to form urea groups. However, the urea groups are less thermally stable than urethane groups in the system, particularly when the urea groups are sterically hindered. At elevated temperatures, for example, near extrusion temperatures, the urea groups revert back to isocyanate and amines. Those isocyanates then less-reversibly react with the unreacted hydroxyl groups. At elevated temperatures, these unreacted amine endgroups accumulate and the overall properties and composition of the polyurethane can vary unpredictably. An exemplary series of reactions is shown below:

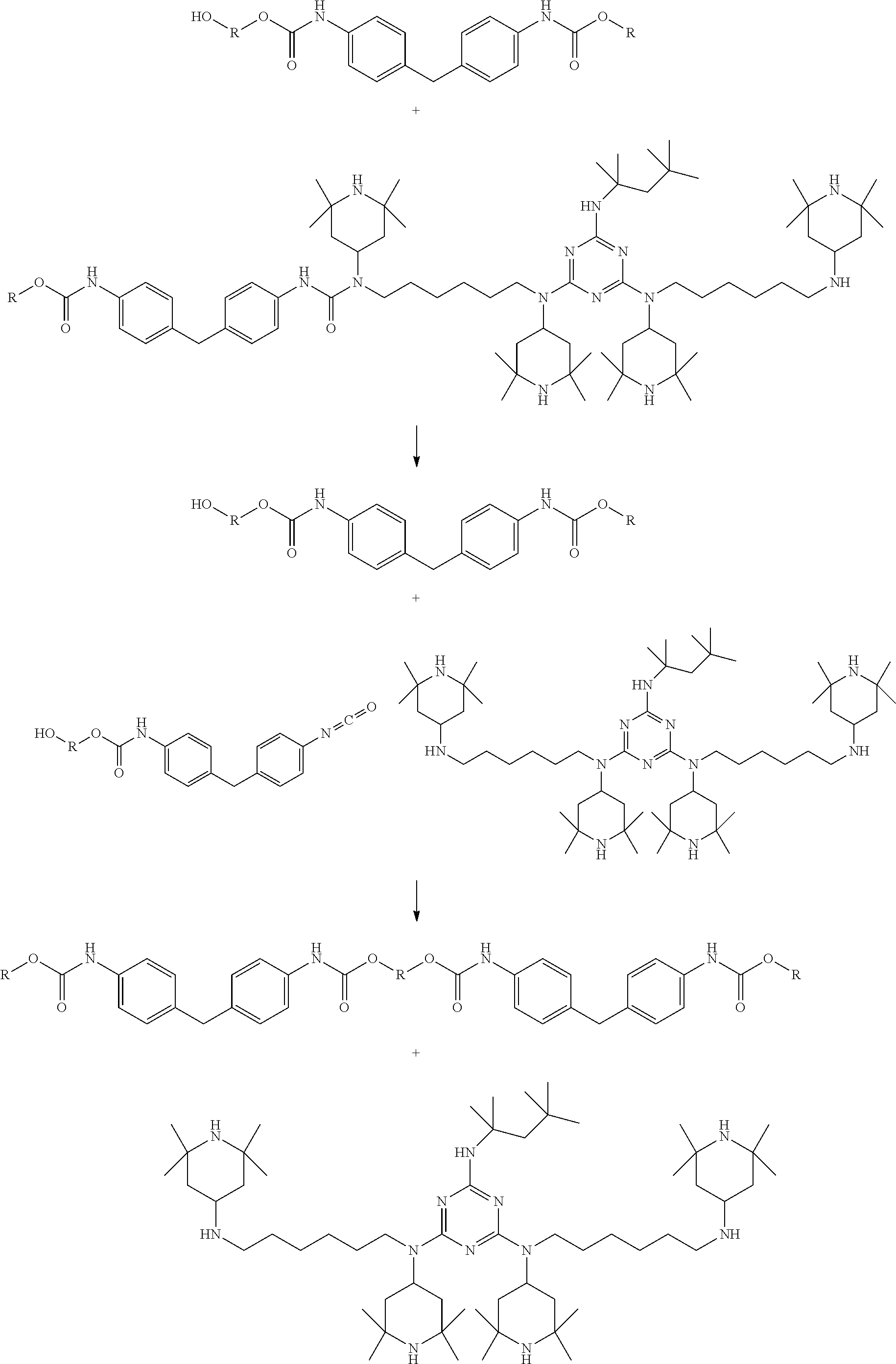

Including a mono-alcohol in the reactive mixture may minimize this problem and create a more stable polyurethane. The end groups of the chains are not excess hydroxyl or amine groups, but rather the reaction product of mono-alcohols and diisocyanates. In this case, to avoid excess hydroxyl groups, the isocyanate index (the mole ratio of isocyanate groups to hydroxyl groups) should be near 1.0 or greater. In some embodiments, the isocyanate index should be 0.99 or greater. In some embodiments, the isocyanate index should be 0.98 or greater. In some embodiments, the isocyanate index should be 0.95 or greater. Here, while the urea groups similarly may, at elevated temperatures, revert to isocyanate and amine groups, there remains no significant number of unreacted hydroxyl end groups. Therefore, the isocyanate is forced to react again with amine to reform the urea group, and the stability of the polyurethane even at reaction extrusion temperatures may be increased.

In some embodiments, the present description is directed to a polyurethane comprising a reaction product of a reactive mixture including a polyol, a diol chain extender, a diisocyanate and a multifunctional amine according to at least one of Formula I and Formula II, having the following structures:

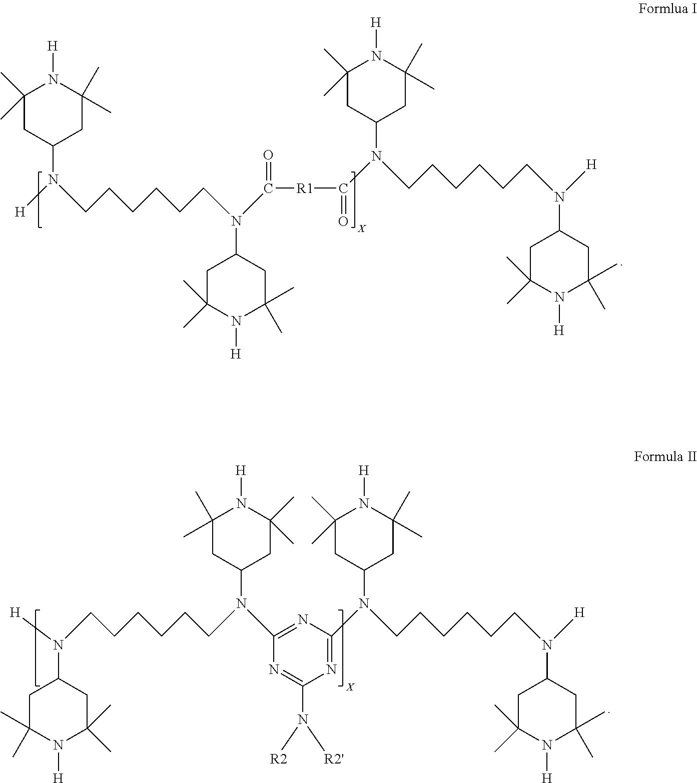

In some embodiments, X is an integer from 0 to 10, inclusive of the endpoints, R1 is a linear or branched aliphatic group, cyclic aliphatic group, aromatic group or a compound containing an aromatic group having from 2 to 20 carbon atoms, R2 is a linear or branched alkyl group having from 1 to 20 carbon atoms and R2′ is hydrogen or a linear or branched alkyl group having from 1 to 20 carbon atoms. In some embodiments, X may be an integer from 0 to 5, from 0 to 3, from 1 to 10, from 1 to 5 or from 1 to 3, inclusive of the endpoints. In some embodiments, R1 is a linear or branched aliphatic group, cyclic aliphatic group, aromatic group or a compound containing an aromatic group having from 2 to 16 carbon atoms, from 2 to 12 carbon atoms or from 2 to 8 carbon atoms. In some embodiments, R2 is a linear or branched alkyl group having from 1 to 16 carbon atoms, from 1 to 12 carbon atoms, from 1 to 10 carbon atoms or from 1 to 8 carbon atoms and/or R2′ is a hydrogen or a linear or branched alkyl group having from 1 to 16 carbon atoms, from 1 to 12 carbon atoms, from 1 to 10 carbon atoms or from 1 to 8 carbon atoms. In some embodiments, R2 is a linear or branched alkyl group having from 1 to 10 carbon atoms and R2′ is a hydrogen. Mixtures of Formula I and Formula II may be used.

The multifunctional amines of Formulas I and Formula II each have two notable features. One feature is that each multifunctional amine contains two less-hindered secondary amines (excluding the pendent amine with R2 substitution of the triazine), i.e. the two carbon atoms in a position alpha to the nitrogen of the less-hindered secondary amine are not tertiary carbon atoms, or equivalently, the two carbon atoms in a position alpha to the nitrogen contain at least one bond to a hydrogen atom. Less-hindered in this case refers to relatively less steric hindrance than amines in a 2,2,6,6-tetramethylpiperidine ring. The less-hindered secondary amine functional groups are subsequently capable of reacting with other components of the reactive mixture. The second feature is that each multifunctional amine includes at least two hindered secondary amines, i.e. the two carbon atoms in a position alpha to the nitrogen of the hindered secondary amine are tertiary carbon atoms, or equivalently, the two carbon atoms in a position alpha to the nitrogen include no bonds to a hydrogen atom. Due to their greater steric hinderance, the hindered secondary amines are typical incapable of reacting with other components of the reactive mixture or the reaction rate is significantly reduced such that they do not play a significant role in forming the polyurethanes of the present description. The number of hindered secondary amines in the multifunctional amines of Formula I and Formula II depends on the value of X. Thus, the number of hindered amines, N, in the multifunctional amines of Formula I and Formula II may vary according to the following: N=2X+2. In some embodiments, the number of hindered secondary amines in the multifunctional amines of Formula I and Formula II may be from 2 to 22, from 2 to 16, from 2 to 12 or from 2 to 8.

During the polymerization of the polyurethanes. the presence of the two less-hindered secondary amines of the multifunctional amines of Formulas I and II enable the compounds to react with the diisocyanate groups of the reaction mixture (covalent bond forming a urea linkage) and to be incorporated into the polyurethanes of the present description, i.e. the multifunctional amines of Formulas I and II become part of the polyurethane backbone. This feature prevents migration and/or diffusion of the multifunctional amines and the compounds may, generally, be uniformly dispersed throughout the polyurethane. This feature also prevents extraction of the multifunctional amines from the polyurethanes during, for example, use as a polishing layer of a CMP pad. During use as a polish layer of a CMP pad, the polyurethanes may contact aqueous and/or non-aqueous polishing solutions that may be capable of extracting components, e.g. lower molecular weight compounds, from the polyurethane, particularly at the surface region of the polyurethane polishing layer. The components may then diffuse into the polishing solutions, i.e. be removed from the polyurethane polishing layer, rendering them ineffective. Due to their covalent bonding into the polyurethane backbone, the multifunctional amines are incapable of being extracted/removed from the polyurethanes of the present description. This behavior contrasts the behavior of multifunctional amines that are incapable of reacting into the polyurethane during synthesis and/or are simply blended into a polyurethane.

As the multifunctional amines are reacted into the polyurethanes of the present description, they may need to be included in the calculation of the stoichiometry of the reactive mixture used to form the polyurethanes. Typically, the stoichiometry of the reactive mixture is calculated based on the ratio of the isocyanate functional groups, associated with the diisocyanate of the reactive mixture, to the hydroxyl functional groups, associated with the polyols and diol chain extender of the reactive mixture. With the inclusion of the multifunctional amine to the reactive mixture, the stoichiometry may be calculated based on the ratio of the isocyanate functional groups, associated with the diisocyanate of the reactive mixture, to the hydroxyl functional groups and less-hindered secondary amine functional groups, associated with the polyol, diol chain extender and the multifunctional amine of the reactive mixture. In some embodiments, the mole ratio of isocyanate groups to hydroxyl groups and less-hindered secondary amine groups, combined, in the reactive mixture is between 0.96 to 1.08, between 0.97 and 1.06, between, 0.98 to 1.04, or between 0.99 to 1.04. In some embodiments, the amount of multifunctional amine in the reactive mixture is greater than 2 percent by wt., greater than 4 percent by wt., greater than 6 percent by wt. or even greater than 8 percent by wt., based on the total weight of the reactive mixture. In some embodiments, the amount of multifunctional amine in the reactive mixture is greater than 2 percent by wt. and less than 15 percent by wt., greater than 3 percent by wt. and less than 15 percent by wt., greater than 4 percent by wt. and less than 15 percent by wt., greater than 4 percent by wt. and less than 12.5 percent by wt. or greater than 6 percent by wt. and less than 10 percent by wt., based on the total weight of the reactive mixture.

The multifunctional amines contain hindered secondary amines and the hindered secondary amines provide an important attribute; they enable the modification of the zeta potential of the polyurethanes of the present description. Typically, polyurethanes will have a zeta potential that is negative over the entire pH range from 2 to 10. Inclusion of the multifunctional amines with their hindered secondary amines into the polyurethane enables the formation of a polyurethane with a higher zeta potential or even a positive zeta potential at acidic pH. Additionally, the zeta potential of the polyurethanes of the present description may be modified or “tuned” based on the amount of multifunctional amine added to the reactive mixture, i.e. covalently bonded into the polyurethane. Generally, the greater the amount of the multifunctional amine incorporated into the polyurethane, the more positive the zeta potential of the polyurethane. The structure of the sterically hindered amines can affect the pH range over which the zeta potential is positive. Sterically hindered amines with a more basic character can adopt a positive zeta potential at higher pH values compared to amines with less basicity. Although not to be bound by theory, the pH range at which the zeta potential becomes positive generally relates to the pKb of the hindered amines. In some embodiments, the pKb of the hindered amine is less than or equal to 6, less than or equal to 5.5, less than or equal to 5.0 or less than or equal to 4.5 and/or greater than or equal to 2.0, greater than or equal to 2.5 or greater than or equal to 3.0. In general, 2,2,6,6-tetramethylpiperidinyl groups with secondary amines are more basic and more preferred than 1,2,2,6,6-pentamethylpiperidinyl groups and similar structures with tertiary amines. The zeta potential of the polyurethane can affect its performance characteristics in certain applications, for example, when the polyurethane is used as a polishing layer in a CMP application. During CMP applications, the polishing layer will typically be in contact with a polishing solution that is a slurry, i.e. contains abrasive particles. The abrasive particles themselves may have a zeta potential that is negative. Although not wishing to be bound by theory, it is thought that polyurethanes that have a negative zeta potential may repel slurry particles that also have a negative zeta potential. This may adversely affect polishing performance by, for example, decreasing the removal rate or increasing the non-uniformity of the removal rate. However, if the polishing pad has a positive zeta potential, this may attract slurry particles having a negative zeta potential to the polishing layer surface and may provide one or more benefits, e.g. increased removal rates.

The multifunctional amines may be prepared by the reaction of N,N′-(bis-2,2,6,6-tetramethylpiperidin-4-yl)hexane-1,6-diamine and at least one of (i) a dihalogenated, alkyl modified 1,3,5-triazin-2-amine, (ii) a diacid and (iii) a diacyl halide. The dihalogenated, alkyl modified 1,3,5-triazin-2-amine may include at least one of chloro, bromo and fluoro substitution. Examples of suitable dihalogented, alkyl modified 1,3,5-triazin-2-amines include 4,6-dichloro-N-octyl-1,3,5-triazin-2-amine, 4,6-dichloro-N,N-dimethyl-1,3,5-triazin-2-amine, 4,6-dichloro-N,N-dipropyl-1,3,5-triazin-2-amine, 4,6-dichloro-N,N-dihexyl-1,3,5-triazin-2-amine, 4,6-dichloro-N-(1,1,3,3-tetramethylbutyl)-1,3,5-triazin-2-amine and the like. Combinations of dihalogented, alkyl modified 1,3,5-triazin-2-amines may be used. An exemplary multifunctional amine that may be prepared from the reaction of N,N′-(bis-2,2,6,6-tetramethylpiperidin-4-yl)hexane-1,6-diamine and a dihalogenated, alkyl modified 1,3,5-triazin-2-amine is Poly[[6-[(1,1,3,3-tetramethylbutyl)amino]-1,3,5-triazin-2,4-iyl][(2,2,6,6-tetramethyl-4-piperidinyl)imino]-1,6-hexanediyl[(2,2,6,6-tetramethyl-4-piperidinyl)imino]]), available under the trade designation CHIMASSORB 944 from, BASF, Florham Park, New Jersey. Examples of suitable diacids include terephthalic acid (e.g., 1,4 terephthalic acid), 1,4 naphthalic acid, isophthalic acid, phthalic acid, 2,6-naphthalenedicarboxylic acid, diphenyldicarboxylic acid, succinic acid, adipic acid, azelaic acid, maleic acid, glutaric acid, suberic acid, sebacic acid, dodecanedionic acid, 1,4-cyclohexanedicarboxylic acid, and the like. Combinations of diacids may be used. Examples of suitable diacyl halides include bromine, chlorine or fluorine substituted diacids, including bromine, chlorine or fluorine substituted diacids of the present description, e.g. 1,4-terephthaloyl dichloride, 1,4-terephthaloyl difluoride, isophthaloyl difluoride, 1,6-hexanedioyl dichloride, 1,4-proanedioyl dibromide and the like. Combinations of diacyl halides may be used.

The reactive mixture includes a polyol. The polyol of the reactive mixture can include any suitable number of hydroxyl groups and includes at least two hydroxyl groups. For example, the polyol can include at least six hydroxyl groups, at least four hydroxyl groups, at least three hydroxyl groups or at least two hydroxyl groups. In some embodiments, the polyol has a number average molecular weight of at least 400 Daltons. In some embodiments, the polyol has a number average molecular weight between 400 Da and 10,000 Da, between 400 Da and 5,000 Da, between 400 Da and 2,000 Da, between 450 Da and 10,000 Da, between 450 Da and 5,000 Da, between 450 Da and 2,000 Da between 500 Da and 10,000 Da, between 500 Da and 5,000 Da or between 500 Da and 2,000 Da. The type of polyol is not particularly limited. Combinations of different types of polyols may be used. In some embodiments, the polyol may be at least one of a polyester polyol, a polyether polyol, a polycarbonate polyol and a hydroxyl terminated butadiene.

In some embodiments, the polyol may be a polyester polyol. The polyester polyol may be a product of a condensation reaction such as a polycondensation reaction. In embodiments where polyester polyol is made according to a condensation reaction, the reaction can be between one or more carboxylic acids and one or more diols. An example of a suitable carboxylic acid includes a carboxylic acid according to Formula III, having the structure:

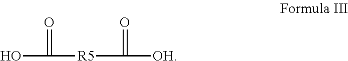

In Formula III, R3 may be chosen from substituted or unsubstituted C1-C40 alkylene, C2-C40 alkylene, C2-C40 alkenylene, C4-C20 arylene, C4-C20 cycloalkylene and C4-C20 aralkylene. Specific examples of suitable carboxylic acids include, but are not limited to, glycolic acid (2-hydroxyethanoic acid), lactic acid (2-hydroxypropanoic acid), succinic acid (butanedioic acid), 3-hydoxybutanoic acid, 3-hydroxypentanoic acid, terepthalic acid (benzene-1,4-dicarboxylic acid), naphthalene dicarboxylic acid, 4-hydroxy benzoic acid, 6-hydroxynaphtalane-2-carboxylic acid, oxalic acid, malonic acid (propanedioic acid), adipic acid (hexanedioic acid), pimelic acid (heptanedioic acid), ethonic acid, suberic acid (octanedioic acid), azelaic acid (nonanedioic acid), sebacic acid (decanedioic acid), glutaric acid (pentanedioic acid), dedecandioic acid, brassylic acid, thapsic acid, maleic acid ((2Z)-but-2-enedioic acid), fumaric acid ((2E)-but-2-enedioic acid), glutaconic acid (pent-2-enedioic acid), 2-decenedioic acid, traumatic acid ((2E)-dodec-2-enedioic acid), muconic acid ((2E,4E)-hexa-2,4-dienedioic acid), glutinic acid, citraconic acid ((2Z)-2-methylbut-2-enedioic acid), mesaconic acid ((2E)-2-methyl-2-butenedioic acid), itaconic acid (2-methylidenebutanedioic acid), malic acid (2-hydroxybutanedioic acid), aspartic acid (2-aminobutanedioic acid), glutamic acid (2-aminopentanedioic acid), tartonic acid, tartaric acid (2,3-dihydroxybutanedioic acid), diaminopimelic acid ((2R,6S)-2,6-diaminoheptanedioic acid), saccharic acid ((2S,3S,4S,5R)-2,3,4,5-tetrahydroxyhexanedioic acid), mexooxalic acid, oxaloacetic acid (oxobutanedioic acid), acetonedicarboxylic acid (3-oxopentanedioic acid), arbinaric acid, phthalic acid (benzene-1,2-dicarboxylic acid), isophthalic acid, diphenic acid, 2,6-naphtalenedicarboxylic acid, or a mixture thereof.

An example of a suitable diol for the condensation reaction includes a diol according to Formula IV, having the structure:

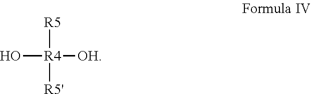

In Formula IV, R4 may be chosen from substituted or unsubstituted C1-C40 alkylene, C2-C40 alkenylene, C4-C20 arylene, C1-C40 acylene, C4-C20 cycloalkylene, C4-C20 aralkylene, and C1-C40 alkoxyene, and R5 and R5′ are independently chosen from —H, substituted or unsubstituted C1-C40 alkyl, C2-C40 alkenyl, C4-C20 aryl, C1-C20 acyl, C4-C20 cycloalkyl, C4-C20 aralkyl, and C1-C40 alkoxy. Suitable polyols include, but are not limited to ethylene glycol, 1,2-propanediol, 1,3-propanediol, 1,3-butanediol, 1,4-butanediol, 1,5-pentane-diol, 1,6-hexanediol, 2,2-dimethyl-1,3-propanediol, 1,4-cyclohexanedimethanol, deca-methylene glycol, dodecamethylene glycol, glycerol, trimethylolpropane, and mixtures thereof.

In some embodiments, the polyol is made via a ring opening polymerization, e.g. the ring opening polymerization of ε-caprolactone.

Suitable polyester polyols include, but are not limited to, polybutylene adipate, polyethylene adipate, poly(diethylene glycol adipate), polyhexamethylene adipate, poly(neopentyl glycol) adipate, poly(butylene adipate-co-phthalate), polycaprolactone or copolymers thereof. Combinations of different polyester polyols may be used.

In some embodiments, the polyol of the reactive mixture may be a polyether polyol, including but not limited to, polyoxyalkylene polyols, polyoxycycloalkylene polyols, and alkylene oxide adducts thereof. In some embodiments, the polyether-polyols may be at least one of polyoxyethylene polyol (e.g. polyethylene glycol), polyoxypropylene polyol (e.g. polypropylene glycol), polyoxytetramethylene polyol (e.g. polyoxytetramethylene glycol), copolymers thereof and mixtures thereof and may have a hydroxyl functionality of from 2 to 6, in particular from 2 to 4.

Polyether polyols are well known and may be prepared by reactions of compounds containing hydroxyl groups with, for example, ethylene oxide, propylene oxide, tetramethylene oxide in the presence of a base catalyst, yielding polyoxyethylene polyol, polyoxypropylene polyol and polyoxytetramethylene, respectively. Copolymers containing at least two of ethylene oxide, propylene oxide and tetramethylene oxide may also be used. A variety of hydroxyl group containing compounds can be used to initiate the reaction including, for example, ethylene glycol, propylene glycol, butylene glycol, glycerine, 2,2-dimethylolpropane, pentaerythritol and the like. Examples of commercially available polyether polyols include Arcol polyether polyols available under the trade designation PPG 425, PPG 725, LHT 112 and LHT 240, (from Arco Chemical Co., Newtown Square, PA); polyethylene glycols such as those available under the trade designation Carbowax Sentry provided (Dow Chemical Co., Midland, MI); PLURACOL E 1450 polyethylene glycol (BASF Corp., Parsippany, NJ); and TERATHANE poly(tetramethylene oxide) polyol (E.I. DuPont de Nemours; Wilmington, DE).

In some embodiments, the polyol of the reactive mixture may be a polycarbonate polyol. The polycarbonate polyol can be obtained from the reaction of aliphatic diols, such as 1,4-butanediol and 1,6-hexanediol, with phosgene, diaryl-carbonates such as diphenylcarbonate or with cyclic carbonates such as ethylene or propylene carbonate. The aliphatic diol may be any one of or combinations of the diols discussed with respect to Formula IV. Examples of commercially available polycarbonate polyols include ARAMACO PERFORMANCE MATERIALS CONVERGE POLYO 212-10, 212-20, CPX-2001-112, CPX-2502-56a and HMA-2 available from Aramaco Performance Materials, LLC, Houston, TX.

In some embodiments, the polyol of the reactive mixture may be or include a hydroxyl terminated butadiene. The hydroxyl terminated butadiene may be a hydroxyl terminated polybutadiene and the polybutadiene may be a homopolymer or copolymer. Examples of commercially available hydroxyl terminated butadienes include “LIQUIFLEX H” from Petroflex, Wilmington. DE, and POLY-BD-45HTLO and Krasol LBH P 2000, both from Cray Valley USA, LLC, Exton, PA. In some embodiments, the polyol of the reactive mixture may be or include a saturated hydroxyl terminated polybutadiene. An example of commercially available saturated hydroxyl terminated poly butadienes is Krasol HLBH P 2000 from Cray Valley USA LLC, Exton, PA.

The polyol may be present in the reaction mixture in an amount between 30 wt. % to 80 wt. % based on the weight of the reactive mixture. In some embodiments the amount of polyol present in the reactive mixture is greater than or equal to 30 wt. %, 35 wt. %, 40 wt. %, 45 wt. %, 50 wt. % and/or less than or equal to 80 wt. %, 75 wt. %, 70 wt. %, 65 wt. % or 60 wt. % based on the weight of the reactive mixture. The polyester polyol may include at least 70% by wt. of a polyester diol, based on the total wt. of the polyester polyol in the reactive mixture. In some embodiment the polyester polyol includes at least 70 wt. %, at least 75 wt. %, at least 80 wt. %, at least 85 wt. %, at least 90 wt. %, at least 95 wt. %, at least 97 wt. %, at least 99 wt. % or 100 wt. % of a polyester diol, based on the weight of the polyester polyol in the reactive mixture.

The reactive mixture includes a diol chain extender. The diol chain extender may be described by Formula IV, where R4 is chosen from substituted or unsubstituted C1-C16 alkylene, C2-C16 alkenylene, C4-C20 arylene, C1-C16 acylene, C4-C16 cycloalkylene, C4-C16 aralkylene, and C1-C16 alkoxyene, and R5 and R5′ are independently chosen from —H, substituted or unsubstituted C1-C16 alkyl, C2-C16 alkenyl, C4-C16 aryl, C1-C16 acyl, C4-C16 cycloalkyl, C4-C16 aralkyl, and Cl-C16 alkoxy and R5 and R5′ are prohibited from being hydroxyl and from having hydroxyl substitution. Suitable diols include, but are not limited to, ethylene glycol, 1,2-propanediol, 1,3-propanediol, 1,3-butanediol, 1,4-butanediol, 1,5-pentanediol, 1,6-hexanediol, 2,2-dimethyl-1,3-propanediol, 1,4-cyclohexanedimethanol, decamethylene glycol, diethylene glycol, hydroquinone bis(2-hydroxyethyl) ether, and dodecamethylene glycol. In some embodiments, the diol chain extender includes at least one of a C1-C16 aliphatic diol and C4-C16 cycloaliphatic diol. In some embodiments, the C1-C16 aliphatic diol includes a C1-C16 alkylene and, optionally, the C1-C16 alkylene is a linear, C2-C16 alkylene with hydroxyl substitution at the two terminal carbon atoms. The diol chain extender can be in a range of from about 1 wt. % to about 15 wt. % of the reaction mixture or from about 2 wt. % to about 15 wt. % of the reactive mixture. In some embodiments, the amount of diol chain extender present in the reactive mixture is greater than or equal to 1 wt. %, 2 wt. %. 3 wt. %, 4 wt. %. 5 wt. %, 6 wt. % and/or less than or equal to 15 wt. %, 14 wt. %. 13 wt. %, 12 wt. % or less than 11 wt. % based on the weight of the reactive mixture. In some embodiments, the diol chain extender has molecular weight of less than 400 Daltons, less than 350 Daltons or less than 300 Daltons. For example, the molecular weight of the diol chain extender can be in a range of from 30 Daltons to less than 400 Daltons, from 30 Daltons to 350 Daltons, 30 Daltons to 300 Daltons or 50 Daltons to less than 400 Daltons. In some embodiments, the molecular weight of the diol chain extender may be the number average molecular weight.

The reactive mixture includes a diisocyanate. The diisocyanate is not particularly limited and can be monomeric, oligomeric or polymeric. An example of a suitable diisocyanate includes a diisocyanate according to Formula V having the structure:

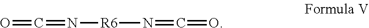

In Formula V, R6 is chosen from substituted or unsubstituted C1-C40 alkylene, C2-C40 alkenylene, C4-C20 arylene, C4-C20 arylene-C1-C40 alkylene-C4-C20 arylene, C4-C20 cycloalkylene, and C4-C20 aralkylene. In some embodiments, the diisocyanate is chosen from dicyclohexylmethane-4,4′-diisocyanate, isophorone diisocyanate, hexamethylene diisocyanate, 1,4-phenylene diisocyanate, 1,3-phenylene diisocyanate, m-xylylene diisocyanate, tolylene-2,4-diisocyanate, tolylene-2,6-diisocyanate, poly(hexamethylene diisocyanate), 1,4-cyclohexylene diisocyanate, 4-chloro-6-methyl-1,3-phenylene diisocyanate, 4,4′-diphenylmethane diisocyanate, 2,4-diphenylmethane diisocyanate, 1,4-diisocyanatobutane, 1,8-diisocyanatooctane, 2,5-toluene diisocyanate, methylene bis(o-chlorophenyl diisocyanate, (4,4-diisocyanato-3,3′,5,5′-tetraethyl) diphenylmethane, 4,4-diisocyanato-3,3′-dimethoxybiphenyl (o-dianisidine diisocyanate), 5-chloro-2,4-toluene diisocyanate, 1-chloromethyl-2,4-diisocyanato benzene, tetramethyl-m-xylylene diisocyanate, 1,12-diisocyanatododecane, 2-methyl-1,5-diisocyanatopentane, 2,2,4-trimethylhexyl diisocyanate, or a mixture thereof.

In some embodiments, the diisocyanate may be a chain extended diisocyanate, i.e. the reaction product of a diisocyanate and a dihydroxyl terminated oligomer or polymer, e.g. a dihydroxyl terminated, linear oligomer or polymer. During the reaction, excess diisocyanate is used to ensure that at least 80% by wt., 90% by wt., 95% by wt., 97% by wt. 98% by wt., 99 wt. % by wt. or 99.5 wt. % of the product of the reaction is also a diisocyanate. The dihydroxyl terminated oligomer or polymer is not particularly limited and may include, for example, dihydroxyl terminated, linear polyesters and dihydroxyl terminated, linear polyethers. Polyester polyols, particularly polyester diols previously discussed with respect to the polyester polyols of the present description may be used to form the chain extended diisocyanate. In some embodiments, the polyester polyol of the chain extended diisocyanate may include the reaction product of one or more C2-C12 diol and one or more C2-C12 diacid. In some embodiments, the diisocyanate includes a diphenylmethane diisocyanate, a reaction product of diphenylmethane diisocyanate and a hydroxyl terminated, linear oligomer or polymer, toluene diisocyanate, a reaction product of toluene diisocyanate and a hydroxyl terminated, linear oligomer or polymer and combinations thereof. One exemplary chain extended diisocyanate is an ethylene-co-butylene adipate polyester terminated with 4,4′-diphenylmethane diisocyanate (MDI) available under the trade designation “RUBINATE 1234”, available from Huntsman Corporation, The Woodlands, TX.

In some embodiments, the amount of diisocyanate in the reaction mixture is between 10 wt. % and 60 wt. % based on the weight of the reactive mixture. In some embodiments, the amount of diisocyanate in the reaction mixture is greater than or equal to 10 wt. %, 15 wt. %, 20 wt. %, 25 wt. % and/or less than or equal to 60 wt. %, 55 wt. %, 50 wt. % or 45 wt. % based on the weight of the reactive mixture.

The reactive mixture may further include a catalyst to facilitate reaction between the polyisocyanate and polyol components. Useful catalysts in the polymerization of polyurethanes include aluminum-, bismuth-, tin-, vanadium-, zinc-, mercury-, and zirconium-based catalysts, amine catalysts, and mixtures thereof. Preferred catalysts include tin based catalysts, such as dibutyl tin compounds. In some embodiments, the catalysts include, but are not limited to, dibutyltin diacetate, dibutyltin dilaurate, dibutyltin di acetyl acetonate, dibutyltin dimercaptide, dibutyltin dioctoate, dibutyltin dimaleate, dibutyltin acetonylacetonate, and dibutyltin oxide. Suitable amounts of the catalyst can be from 0.001% to 1%, from 0.001% to 0.5% or from 0.001% to 0.25%. In some embodiments, the amount of catalyst in the reactive mixture may be greater than or equal to 0.001 wt %, 0.002 wt %, 0.005 wt %, 0.01 wt %, 0.02 wt %, 0.05 wt %, 0.07 wt %, 0.1 wt % and/or less than or equal to 1.0 wt. %, 0.7 wt. %, 0.5 wt. % or 0.3 wt. %, based on the weight of the reactive mixture.

In some embodiments, the reaction mixture may contain a polyol having at least three hydroxyl groups and/or a polyisocyanate having at least three corresponding isocyanate groups. In this case, the polyol and or polyisocyante may act as a branching agent. The amount of polyol and/or polyisocynate must be limited, in order to maintain the general thermoplastic characteristics of the resulting polyurethane. However, components of this nature may be used to increase the molecular weight or modify the viscosity characteristic of the polyurethane.

In some embodiments, the reactive mixture includes a mono-alcohol. In some embodiments, the mono-alcohol may be a fatty alcohol. Fatty alcohols are typically straight chain primary alcohols with a hydroxyl end group. Fatty alcohols include 1-decanol, dodecanol, stearyl, oleyl, and lauryl alcohols. The fatty alcohol may be a C6-C12 fatty alcohol, although fatty alcohols having any chain length between C4-C26 may be useful in certain embodiments. In some embodiments, the reactive mixture includes a mono-alcohol with a relatively high boiling point to prevent evaporation of the mono-alcohol before the urethane polymerization is complete. The mono-alcohol may have a boiling point greater than the reaction temperature during the urethane polymerization. In some embodiments, the mono-alcohol includes a branched aliphatic group. In some embodiments, the mono-alcohol has a chain length between C8-C24, and in some embodiments, the mono-alcohol has a chain length between C10-C20. Branched mono-alcohols include 2-ethyl-1-hexanol, 2-butyl-1-octanol, 2-pentyl-1-nonanol, 2-hexyl-1-decanol, 2-octyl-1-dodecanol, 2-decyl-1-tetradecanol, isooctanol, isodecanol, isododecanol, 2,4,4-trimethyl-1-pentanol, and 3,5,5-trimethyl-1-hexanol. In some embodiments, the mono-alcohol may be a secondary alcohol. Secondary mono-alcohols include 2-octanol, 3-octanol, 4-octanol, 2-nonanol, 4-nonanol, 5-nonanol, 2-decanol, and 2-dodecanol. In some embodiments, the mono-alcohol may contain ether groups. Ether-containing mono-alcohols include diethylene glycol monobutyl ether, diethylene glycol monoethyl ether, diethylene glycol monomethyl ether, ethylene glycol monobutyl ether, di(propylene glycol) butyl ether, di(propylene glycol) propyl ether, di(propylene glycol) methyl ether, propylene glycol butyl ether, and propylene glycol propyl ether.

Other additives may be included in the reactive mixture and polyurethanes of the present description, including but not limited to antioxidants, light/UV light stabilizers, dyes, colorants, filler particles, abrasive particles, reinforcing particles or fibers, viscosity modifiers and the like. Additives that are not soluble in the reactive mixture, e.g. filler particles, abrasive particles, and reinforcing particles or fibers, are not included in the calculation of the weight percent of the components of the reactive mixture, i.e., they are not included in the total weight of the reactive mixture which is used as the basis for the wt. percentage of each component of the reactive mixture.

The polyurethanes of the present description may have stable viscosity at the processing conditions, e.g., temperature, pressure and time, used to fabricate articles therefrom. The viscosity of the polyurethanes at 200° C. may be less than 1,000,000 cP, less than 3,000,000 cP, less than 5,000,000 cP, less than 10,000,000 cP or less than 15,000,000 cP and/or greater than 100,000 cP, greater than 75,000 cP, greater than 50,000 cP, greater than 40,000 cP or greater than 35,000 cP.

The polyurethanes of the present description can be used in a variety of applications and arc particularly well suited for the formation of thin films. Due to their unique chemical resistance, abrasion resistance, zeta potential and moldability, the polyurethanes of the present description are particularly useful as a polishing layer in, for example, a polishing pad. In one embodiment, the present description provides a polishing pad comprising a polishing layer having a working surface and a second surface opposite the working surface, wherein the polishing layer includes the polyurethane of any one of embodiments of the present description. Optionally, the polishing layer may include at least 90% by weight, at least 95% by weight, at least 99% by weight or 100% by weight of the polyurethane.

In many polishing applications, e.g., CMP applications, it is generally desirable to have the working surface of the polishing layer of a polishing pad include topography, i.e. be non-planar. The topography may be formed by abrading a substantially planar polishing layer surface with the abrading surface of a pad conditioner. The abrasive particles of the pad conditioner remove regions of the polishing layer surface in a, generally, random fashion and subsequently create topography in the polishing layer surface. Another method to produce topography in the working surface of a polishing layer of a polishing pad is through a micro-replication process, e.g. an embossing process. Such a process provides a working surface of the polishing layer that is precisely designed and engineered to have a plurality of reproducible topographical features, including asperities and/or pores. The asperities and pores are designed to have dimensions ranging from millimeters down to micrometers, with exemplary achievable tolerances being as low as 1 micrometer or less. Due to the precisely engineered asperity topography of the polishing layer, the polishing pads of the present description may be used without a pad conditioning process, eliminating the need for an abrasive pad conditioner and the corresponding conditioning process. Additionally, the precisely engineered pore topography ensures uniform pores size and distribution across the polishing pad working surface, which may lead to improved polishing performance and lower polishing solution usage. Due to their stable flow characteristics, the polyurethanes of the present description are particularly well suited for the fabrication of precisely engineered asperity and pore topography in the working surface of a polishing layer and are capable of meeting the demanding tolerances of said designs. Polishing pads and polishing layers which may employ the polyurethanes of the present description are disclosed in, for example, U.S. Pat. No. 10,252,396, which is incorporated herein by reference in its entirety.

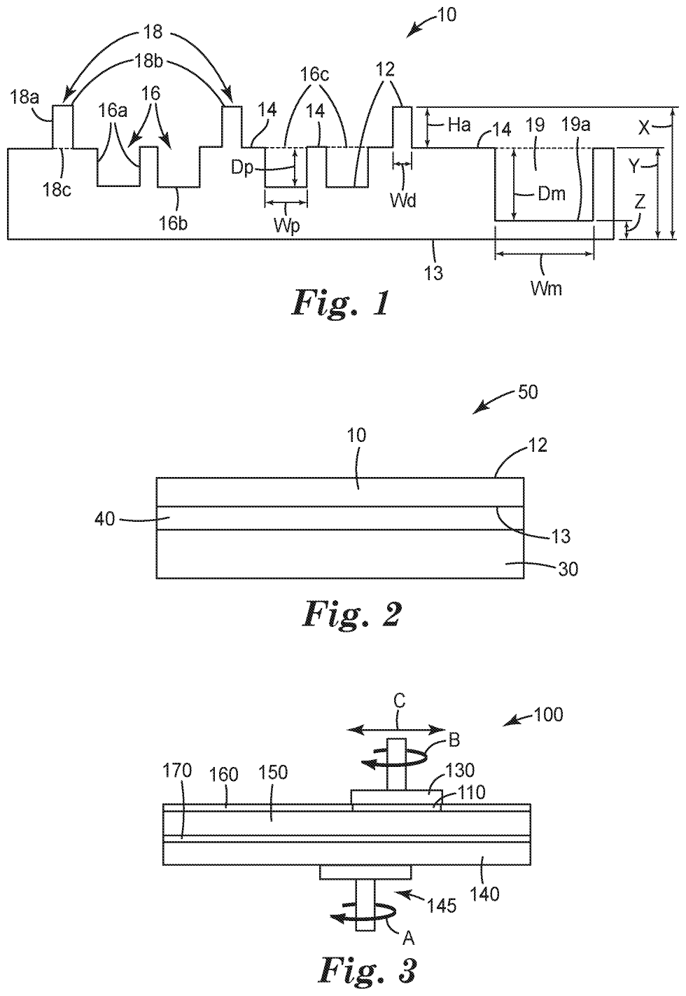

A schematic cross-sectional diagram of a portion of a polishing layer 10 according to some embodiments of the present description is shown in FIG. 1. Polishing layer 10, having thickness X, includes working surface 12 and second surface 13 opposite working surface 12. Working surface 12 is a precisely engineered surface having precisely engineered topography. The working surface includes at least one of a plurality of precisely shaped pores, precisely shaped asperities and combinations thereof. Working surface 12 includes a plurality of precisely shaped pores 16 having a depth Dp, sidewalls 16a and bases 16b and a plurality of precisely shaped asperities 18 having a height Ha, sidewalls 18a and distal ends 18b, the distal ends having width Wd. The width of the precisely shaped asperities and asperity bases may be the same as the width of their distal ends, Wd. Land region 14 is located in areas between precisely shaped pores 16 and precisely shaped asperities 18 and may be considered part of the working surface. The intersection of a precisely shaped asperity sidewall 18a with the surface of land region 14 adjacent thereto defines the location of the bottom of the asperity and defines a set of precisely shaped asperity bases 18c. The intersection of a precisely shaped pore sidewall 16a with the surface of land region 14 adjacent thereto is considered to be the top of the pore and defines a set of precisely shaped pore openings 16c, having a width Wp. As the bases of the precisely shaped asperities and the openings of adjacent precisely shaped pores are determined by the adjacent land region, the asperity bases are substantially coplanar relative to at least one adjacent pore opening. In some embodiment, a plurality of the asperity bases are substantially coplanar relative to at least one adjacent pore opening. A plurality of asperity bases may include at least about 10%, at least about 30%, at least about 50%, at least about 70%, at least about 80%, at least about 90%, at least about 95%, at least about 97%, at least about 99% or even at least about 100% of the total asperity bases of the polishing layer. The land region provides a distinct area of separation between the precisely shaped features, including separation between adjacent precisely shaped asperities and precisely shaped pores, separation between adjacent precisely shaped pores, and/or separation between adjacent precisely shaped asperities. In some embodiments, the working surface includes a land region and at least one of a plurality of precisely shaped pores and a plurality of precisely shaped asperities.

Land region 14 may be substantially planar and have a substantially uniform thickness, Y, although minor curvature and/or thickness variations consistent with the manufacturing process may be present. As the thickness of the land region, Y, must be greater than the depth of the plurality of precisely shaped pores, the land region may be of greater thickness than other abrasive articles known in the art that may have only asperities. In some embodiments of the present description, when both precisely shaped asperities and precisely shaped pores are both present in the polishing layer, the inclusion of a land region allows one to design the areal density of the plurality of precisely shaped asperities independent of the areal density of the plurality precisely shaped pores, providing greater design flexibility. This is in contrast to conventional pads which may include forming a series of intersecting grooves in a, generally, planar pad surface. The intersecting grooves lead to the formation of a textured working surface, with the grooves (regions where material was removed from the surface) defining the upper regions of the working surface (regions where material was not removed from the surface), i.e. regions that would contact the substrate being abraded or polished. In this known approach, the size, placement and number of grooves define the size, placement and number of upper regions of the working surface, i.e. the areal density of the upper regions of working surface are dependent on the areal density of the grooves. The grooves also may run the length of the pad allowing the polishing solution to flow out of the groove, in contrast to a pore that can contain the polishing solution. Particularly, the inclusion of precisely shaped pores, which can hold and retain the polishing solution proximate to the working surface, may provide enhanced polishing solution delivery for demanding applications, e.g. CMP.

Polishing layer 10 may include at least one macro-channel. FIG. 1 shows macro-channel 19 having width Wm, a depth Dm and base 19a. A secondary land region having a thickness, Z, is defined by macro-channel base 19a. The secondary land region defined by the base of the macro-channel would not be considered part of land region 14, previously described. In some embodiments, one or more secondary pores (not shown) may be included in at least a portion of the base of the at least one macro-channel. The one or more secondary pores have secondary pore openings (not shown), the secondary pore openings being substantially coplanar with base 19a of the macro-channel 19. In some embodiments, the base of the at least one macro-channel is substantially free of secondary pores. In some embodiments, the polishing layer includes a plurality of independent or inter-connected macro-channels.

The shape of precisely shaped pores 16 is not particularly limited and includes, but is not limited to, cylinders, half spheres, cubes, rectangular prism, triangular prism, hexagonal prism, triangular pyramid, 4, 5 and 6-sided pyramids, truncated pyramids, cones, truncated cones and the like. The lowest point of a precisely shaped pore 16, relative to the pore opening, is considered to be the bottom of the pore. The shape of all the precisely shaped pores 16 may all be the same or combinations may be used. In some embodiments, at least about 10%, at least about 30%, at least about 50%. at least about 70%, at least about 90%, at least about 95%, at least about 97%, at least about 99% or even at least about 100% of the precisely shaped pores are designed to have the same shape and dimensions. Due to the precision fabrication processes used to fabricate the precisely shaped pores, the tolerances are, generally, small. For a plurality of precisely shaped pores designed to have the same pore dimensions, the pore dimensions are uniform. In some embodiments, the standard deviation of at least one distance dimension corresponding to the size of the plurality of precisely shaped pores: e.g. height, width of a pore opening, length, and diameter; is less than about 20%, less than about 15%, less than about 10%, less than about 8%, less than about 6% less than about 4%, less than about 3%, less than about 2%, or even less than about 1% of the average of the distance dimension. The standard deviation can be measured by known statistical techniques. The standard deviation may be calculated from a sample size of at least 5 pores, or even at least 10 pores at least 20 pores. The sample size may be no greater than 200 pores, no greater than 100 pores or even no greater than 50 pores. The sample may be selected randomly from a single region on the polishing layer or from multiple regions of the polishing layer.

The longest dimension of the precisely shaped pore openings 16c, e.g. the diameter when the precisely shaped pores 16 are cylindrical in shape, may be less than about 10 mm, less than about 5 mm, less than about 1 mm, less than about 500 micrometers, less than about 200 micrometers, less than about 100 micrometers, less than about 90 micrometers, less than about 80 micrometers, less than about 70 micrometers or even less than about 60 micrometers. The longest dimension of the precisely shaped pore openings 16c may be greater than about 1 micrometer, greater than about 5 micrometers, greater than about 10 micrometers, greater than about 15 micrometers or even greater than about 20 micrometers. The cross-sectional area of the precisely shaped pores 16, e.g. a circle when the precisely shaped pores 16 are cylindrical in shape, may be uniform throughout the depth of the pore, or may decrease, if the precisely shaped pore sidewalls 16a taper inward from opening to base, or may increase, if the precisely shaped pore sidewalls 16a taper outward. The precisely shaped pore openings 16c may all have about the same longest dimensions or the longest dimension may vary between precisely shaped pore openings 16c or between sets of different precisely shaped pore openings 16c, per design. The width, Wp, of the precisely shaped pore openings may be equal to the values give for the longest dimension, described above.

The depth of the plurality of precisely shaped pores, Dp, is not particularly limited. In some embodiments, the depth of the plurality of precisely shaped pores is less than the thickness of the land region adjacent to each precisely shaped pore, i.e. the precisely shaped pores are not through-holes that go through the entire thickness of land region 14. This enables the pores to trap and retain fluid proximate the working surface. Although the depth of the plurality of precisely shaped pores may be limited as indicated above, this does not prevent the inclusion of one or more other through-holes in the pad, e.g. through-holes to provide polishing solution up through the polishing layer to the working surface or a path for airflow through the pad. A through-hole is defined as a hole going through the entire thickness, Y, of the land region 14.

In some embodiments, the polishing layer is free of through-holes. As the pad is often mounted to another substrate, e.g. a sub-pad or platen during use, via an adhesive, e.g. a pressure sensitive adhesive, through-holes may allow the polishing solution to seep through the pad to the pad-adhesive interface. The polishing solution may be corrosive to the adhesive and cause a detrimental loss in the integrity of the bond between the pad and the substrate to which it is attached.

The depth, Dp, of the plurality of precisely shaped pores 16 may be less than about 5 mm, less than about 1 mm, less than about 500 micrometers, less than about 200 micrometers, less than about 100 micrometers, less than about 90 micrometers, less than about 80 micrometers, less than about 70 micrometers or even less than about 60 micrometers. The depth of the precisely shaped pores 16 may be greater than about 1 micrometer, greater than about 5 micrometers, greater than about 10 micrometers, greater than about 15 micrometers or even greater than about 20 micrometers. The depth of the plurality precisely shaped pores may be between about 1 micrometer and about 5 mm, between about 1 micrometer and about 1 mm, between about 1 micrometer and about 500 micrometers, between about 1 micrometers and about 200 micrometers, between about 1 micrometers and about 100 micrometers, 5 micrometer and about 5 mm, between about 5 micrometer and about 1 mm, between about 5 micrometer and about 500 micrometers, between about 5 micrometers and about 200 micrometers or even between about 5 micrometers and about 100 micrometers The precisely shaped pores 16 may all have the same depth or the depth may vary between precisely shaped pores 16 or between sets of different precisely shaped pores 16.

In some embodiment, the depth of at least about 10%, at least about 30% at least about 50%, at least 70%, at least about 80%, at least about 90%, at least about 95% or even at least about 100% of the plurality precisely shaped pores is between about 1 micrometer and about 500 micrometers, between about 1 micrometer and about 200 micrometers, between about 1 micrometer and about 150 micrometers, between about 1 micrometer and about 100 micrometer, between about 1 micrometer and about 80 micrometers, between about 1 micrometer and about 60 micrometers, between about 5 micrometers and about 500 micrometers, between about 5 micrometer and about 200 micrometers, between about 5 micrometers and 150 micrometers, between about 5 micrometer and about 100 micrometer, between about 5 micrometer and about 80 micrometers, between about 5 micrometer and about 60 micrometers, between about 10 micrometers and about 200 micrometers, between about 10 micrometers and about 150 micrometers or even between about 10 micrometers and about 100 micrometers.

In some embodiments, the depth of at least a portion of, up to and including all, the plurality of precisely shaped pores is less than the depth of at least a portion of the at least one macro-channel. In some embodiments, the depth of at least about 50%, at least about 60%, at least about 70%, at least about 80%, at least about 90%, at least about 95%, at least about 99% or even at least about 100% of the plurality of precisely pores is less than the depth of at least a portion of a macro-channel.

The precisely shaped pores 16 may be uniformly distributed, i.e. have a single areal density, across the surface of polishing layer 10 or may have different areal density across the surface of polishing layer 10. The areal density of the precisely shaped pores 16 may be less than about 1,000,000/mm², less than about 500,000/mm², less than about 100,000/mm², less than about 50,000/mm², less than about 10,000/mm², less than about 5,000/mm², less than about 1,000/mm², less than about 500/mm², less than about 100/mm², less than about 50/mm², less than about 10/mm², or even less than about 5/mm². The areal density of the precisely shaped pores 16 may be greater than about 1/dm², may be greater than about 10/dm², greater than about 100/dm², greater than about 5/cm², greater than about 10/cm², greater than about 100/cm², or even greater than about 500/cm².

The ratio of the total cross-sectional area of the precisely shaped pore openings 16c, to the projected polishing pad surface area may be greater than about 0.5%, greater than about 1%, greater than about 3% greater than about 5%, greater than about 10%, greater than about 20%, greater than about 30%, greater than about 40% or even greater than about 50%. The ratio of the total cross-sectional arca of the precisely shaped pore openings 16c, with respect to the projected polishing pad surface arca may be less than about 90%, less than about 80%, less than about 70%, less than about 60%, less than about 50% less than about 40%, less than about 30%, less than about 25% or even less than about 20%. The projected polishing pad surface area is the area resulting from projecting the shape of the polishing pad onto a plane. For example, a circular shaped polishing pad having a radius, r, would have a projected surface area of pi times the radius squared, i.e. the area of the projected circle on a plane.

The precisely shaped pores 16 may be arranged randomly across the surface of polishing layer 10 or may be arranged in a pattern, e.g. a repeating pattern, across polishing layer 10. Patterns include, but are not limited to, square arrays, hexagonal arrays and the like. Combination of patterns may be used.

The shape of precisely shaped asperities 18 is not particularly limited and includes, but is not limited to, cylinders, half spheres, cubes, rectangular prism, triangular prism, hexagonal prism, triangular pyramid, 4, 5 and 6-sided pyramids, truncated pyramids, cones, truncated cones and the like. The intersection of a precisely shaped asperity sidewall 18a with the land region 14 is considered to be the base of the asperity. The highest point of a precisely shaped asperity 18, as measured from the asperity base 18c to a distal end 18b, is considered to be the top of the asperity and the distance between the distal end 18b and asperity base 18c is the height of the asperity. The shape of all the precisely shaped asperities 18 may all be the same or combinations may be used. In some embodiments, at least about 10%, at least about 30%, at least about 50%, at least about 70%, at least about 90%, at least about 95%, at least about 97%, at least about 99% or even at least about 100% of the precisely shaped asperities are designed to have the same shape and dimensions. Due to the precision fabrication processes used to fabricate the precisely shaped asperities, the tolerances arc, generally, small. For a plurality of precisely shaped asperities designed to have the same asperity dimensions, the asperity dimensions are uniform. In some embodiments, the standard deviation of at least one distance dimension corresponding to the size of a plurality of precisely shaped asperities, e.g. height, width of a distal end, width at the base, length, and diameter, is less than about 20%, less than about 15%, less than about 10%, less than about 8%, less than about 6% less than about 4%, less than about 3%, less than about 2%, or even less than about 1% of the average of the distance dimension. The standard deviation can be measured by known statistical techniques. The standard deviation may be calculated from a sample size of at least 5 asperities at least 10 asperities or even at least 20 asperities or even more. The sample size may be no greater than 200 asperities, no greater than 100 asperities or even no greater than 50 asperities. The sample may be selected randomly from a single region on the polishing layer or from multiple regions of the polishing layer.

In some embodiments, at least about 50%, at least about 70%, at least about 90%, at least about 95%, at least about 97%, at least about 99% and even at least about 100% of the precisely shaped asperities are solid structures. A solid structure is defined as a structure that contains less than about 10%, less than about 5%, less than about 3%, less than about 2%, less than about 1%, less than about 0.5% or even 0% porosity by volume. Porosity may include open cell or closed cell structures, as would be found for example in a foam, or machined holes purposely fabricated in the asperities by known techniques, such as, punching, drilling, die cutting, laser cutting, water jet cutting and the like. In some embodiments, the precisely shaped asperities are free of machined holes. As a result of the machining process, machined holes may have unwanted material deformation or build-up near the edge of the hole that can cause defects in the surface of the substrates being polished, e.g. semiconductor wafers.

The longest dimension, with respect to the cross-sectional area of the precisely shaped asperities 18, e.g. the diameter when the precisely shaped asperities 18 are cylindrical in shape, may be less than about 10 mm, less than about 5 mm, less than about 1 mm, less than about 500 micrometers, less than about 200 micrometers, less than about 100 micrometers, less than about 90 micrometers, less than about 80 micrometers, less than about 70 micrometers or even less than about 60 micrometers. The longest dimension of the of the precisely shaped asperities 18 may be greater than about 1 micrometer, greater than about 5 micrometers, greater than about 10 micrometers, greater than about 15 micrometers or even greater than about 20 micrometers. The cross-sectional area of the precisely shaped asperities 18, e.g., a circle when the precisely shaped asperities 18 are cylindrical in shape, may be uniform throughout the height of the asperities, or may decrease, if the precisely shaped asperities' sidewalls 18a taper inward from the top of the asperity to the base, or may increase, if the precisely shaped asperities' sidewalls 18a taper outward from the top of the asperity to the bases. The precisely shaped asperities 18 may all have the same longest dimension or the longest dimension may vary between precisely shaped asperities 18 or between sets of different precisely shaped asperities 18, per design. The width, Wd, of the distal ends of the precisely shaped asperity bases may be equal to the values give for the longest dimension, described above. The width of the precisely shaped asperity bases may be equal to the values give for the longest dimension, described above.

The height of the precisely shaped asperities 18 may be less than about 5 mm, less than about 1 mm, less than about 500 micrometers, less than about 200 micrometers, less than about 100 micrometers, less than about 90 micrometers, less than about 80 micrometers, less than about 70 micrometers or even less than about 60 micrometers. The height of the precisely shaped asperities 18 may be greater than about 1 micrometer, greater than about 5 micrometers, greater than about 10 micrometers, greater than about 15 micrometers or even greater than about 20 micrometers. The precisely shaped asperities 18 may all have the same height or the height may vary between precisely shaped asperities 18 or between sets of different precisely shaped asperities 18. In some embodiments, the polishing layer's working surface includes a first set of precisely shaped asperities and at least one second set of precisely shaped asperities wherein the height of the first set of precisely shaped asperities is greater than the height of the seconds set of precisely shaped asperities. Having multiple sets of a plurality of precisely shaped asperities, each set having different heights, may provide different planes of polishing asperities. This may become particularly beneficial, if the asperity surfaces have been modified to be hydrophilic, and, after some degree of polishing the, first set of asperities are worn down (including removal of the hydrophilic surface), allowing the second set of asperities to make contact with the substrate being polished and provide fresh asperities for polishing. The second set of asperities may also have a hydrophilic surface and enhance polishing performance over the worn first set of asperities. The first set of the plurality of precisely shaped asperities may have a height between 3 micrometers and 50 micrometers, between 3 micrometers and 30 micrometers, between 3 micrometers and 20 micrometers, between 5 micrometers and 50 micrometers, between 5 micrometers and 30 micrometers, between 5 micrometers and 20 micrometers, between 10 micrometers and 50 micrometers, between 10 micrometers and 30 micrometers, or even between 10 micrometers and 20 micrometers greater than the height of the at least one second set of the plurality of precisely shaped asperities.

In some embodiment, in order to facilitate the utility of the polishing solution at the polishing layer-polishing substrate interface, the height of at least about 10%, at least about 30% at least about 50%, at least 70%, at least about 80%, at least about 90%, at least about 95% or even at least about 100% of the plurality precisely shaped asperities is between about 1 micrometer and about 500 micrometers, between about 1 micrometer and about 200 micrometers, between about 1 micrometer and about 100 micrometer, between about 1 micrometer and about 80 micrometers, between about 1 micrometer and about 60 micrometers, between about 5 micrometers and about 500 micrometers, between about 5 micrometer and about 200 micrometers, between about 5 micrometers and about 150 micrometers, between about 5 micrometer and about 100 micrometer, between about 5 micrometer and about 80 micrometers, between about 5 micrometer and about 60 micrometers, between about 10 micrometers and about 200 micrometers, between about 10 micrometers and about 150 micrometers or even between about 10 micrometers and about 100 micrometers.

The precisely shaped asperities 18 may be uniformly distributed, i.e., have a single areal density, across the surface of the polishing layer 10 or may have different areal density across the surface of the polishing layer 10. The areal density of the precisely shaped asperities 18 may be less than about 1,000,000/mm², less than about 500,000/mm², less than about 100,000/mm², less than about 50,000/mm², less than about 10,000/mm², less than about 5,000/mm², less than about 1,000/mm², less than about 500/mm², less than about 100/mm², less than about 50/mm², less than about 10/mm², or even less than about 5/mm². The areal density of the precisely shaped asperities 18 may be greater than about 1/dm², may be greater than about 10/dm², greater than about 100/dm², greater than about 5/cm², greater than about 10/cm², greater than about 100/cm², or even greater than about 500/cm². In some embodiments, the areal density of the plurality of precisely shaped asperities is independent of the areal density of the plurality precisely shaped pores.

The precisely shaped asperities 18 may be arranged randomly across the surface of polishing layer 10 or may be arranged in a pattern, e.g., a repeating pattern, across polishing layer 10. Patterns include, but are not limited to, square arrays, hexagonal arrays and the like. Combination of patterns may be used.

The total cross-sectional area of distal ends 18b with respect to the total projected polishing pad surface area may be greater than about 0.01%, greater than about 0.05%, greater than about 0.1%, greater than about 0.5%, greater than about 1%, greater than about 3% greater than about 5%, greater than about 10%, greater than about 15%, greater than about 20% or even greater than about 30%. The total cross-sectional area of distal ends 18b of precisely shaped asperities 18 with respect to the total projected polishing pad surface area may be less than about 90%, less than about 80%, less than about 70%, less than about 60%, less than about 50% less than about 40%, less than about 30%, less than about 25% or even less than about 20%. The total cross-sectional area of the precisely shaped asperity bases with respect to the total projected polishing pad surface area may be the same as described for the distal ends.

The polishing layer, by itself, may function as a polishing pad. The polishing layer may be in the form of a film that is wound on a core and employed in a “roll to roll” format during use. The polishing layer may also be fabricated into individual pads, e.g. a circular shaped pad, as further discussed below. According to some embodiments of the present description, the polishing pad, which includes a polishing layer, may also include a subpad. FIG. 2 shows a polishing pad 50 which includes a polishing layer 10, having a working surface 12 and second surface 13 opposite working surface 12, and a subpad 30 adjacent to second surface 13. Optionally, a foam layer 40 is interposed between the second surface 13 of the polishing layer 10 and the subpad 30. The various layers of the polishing pad can be adhered together by any techniques known in the art, including using adhesives, e.g., pressure sensitive adhesives (PSAs), hot melt adhesives and cure in place adhesives. In some embodiments, the polishing pad includes an adhesive layer adjacent to the second surface. Use of a lamination process in conjunction with PSAs, e.g., PSA transfer tapes, is one particular process for adhering the various layers of polishing pad 50. Subpad 30 may be any of those known in the art. Subpad 30 may be a single layer of a relatively stiff material, e.g., polycarbonate, or a single layer of a relatively compressible material, e.g., an elastomeric foam. The subpad 30 may also have two or more layers and may include a substantially rigid layer (e.g., a stiff material or high modulus material like polycarbonate, polyester and the like) and a substantially compressible layer (e.g., an elastomer or an elastomeric foam material). Foam layer 40 may have a durometer from between about 20 Shore D to about 90 Shore D. Foam layer 40 may have a thickness from between about 125 micrometer and about 5 mm or even between about 125 micrometer and about a 1000 micrometer.

In some embodiments of the present description, which include a subpad having one or more opaque layers, a small hole may be cut into the subpad creating a “window”. The hole may be cut through the entire subpad or only through the one or more opaque layers. The cut portion of the supbad or one or more opaque layers is removed from the subpad, allowing light to be transmitted through this region. The hole is pre-positioned to align with the endpoint window of the polishing tool platen and facilitates the use of the wafer endpoint detection system of the polishing tool, by enabling light from the tool's endpoint detection system to travel through the polishing pad and contact the wafer. Light based endpoint polishing detection systems are known in the art and can be found, for example, on MIRRA and REFLEXION LK CMP polishing tools available from Applied Materials, Inc., Santa Clara, California. Polishing pads of the present description can be fabricated to run on such tools and endpoint detection windows which are configured to function with the polishing tool's endpoint detection system can be included in the pad. In one embodiment, a polishing pad including any one of the polishing layers of the present description can be laminated to a subpad. The subpad includes at least one stiff layer, e.g., polycarbonate, and at least one compliant layer, e.g., an elastomeric foam, the clastic modulus of the stiff layer being greater than the clastic modulus of the compliant layer. The compliant layer may be opaque and prevent light transmission required for endpoint detection. The stiff layer of the subpad is laminated to the second surface of the polishing layer, typically through the use of a PSA, e.g., transfer adhesive or tape. Prior to or after lamination, a hole may be die cut, for example, by a standard kiss cutting method or cut by hand, in the opaque compliant layer of the subpad. The cut region of the compliant layer is removed creating a “window” in the polishing pad. If adhesive residue is present in the hole opening, it can be removed, for example, through the use of an appropriate solvent and/or wiping with a cloth or the like. The “window” in the polishing pad is configured such that, when the polishing pad is mounted to the polishing tool platen, the window of the polishing pad aligns with the endpoint detection window of the polishing tool platen. The dimensions of the hole may be, for example, up to 5 cm wide by 20 cm long. The dimensions of the hole are, generally, the same or similar in dimensions as the dimensions of the endpoint detection window of the platen.

The polishing pad thickness is not particularly limited. The polishing pad thickness may coincide with the required thickness to enable polishing on the appropriate polishing tool. The polishing pad thickness may be greater than about 25 micrometers, greater than about 50 micrometers, greater than about 100 micrometers or even greater than 250 micrometers; less than about 20 mm, less than about 10 mm, less than about 5 mm or even less than about 2.5 mm. The shape of the polishing pad is not particularly limited. The pads may be fabricated such that the pad shape coincides with the shape of the corresponding platen of the polishing tool the pad will be attached to during use. Pad shapes, such as circular, square, hexagonal and the like may be used. A maximum dimension of the pad, e.g., the diameter for a circular shaped pad, is not particularly limited. The maximum dimension of a pad may be greater than about 10 cm, greater than about 20 cm, greater than about 30 cm, greater than about 40 cm, greater than about 50 cm, greater than about 60 cm; less than about 2.0 meter, less than about 1.5 meter or even less than about 1.0 meter. As disused above, the pad, including the polishing layer, the subpad, the optional foam layer and any combination thereof, may include a window, i.e., a region allowing light to pass through, to enable standard endpoint detection techniques used in polishing processes, e.g., wafer endpoint detection.

In some embodiments, the polishing layer may be a unitary sheet. A unitary sheet includes only a single layer of material (i.e., it is not a multi-layer construction, e.g., a laminate) and the single layer of material has a single composition. The composition may include multiple-components, e.g., a polymer blend or a polymer-inorganic composite. Use of a unitary sheet as the polishing layer may provide cost benefits, due to minimization of the number of process steps required to form the polishing layer. A polishing layer that includes a unitary sheet may be fabricated from techniques know in the art, including, but not limited to, molding and embossing. Due to the ability to form a polishing layer having precisely shaped, asperities and/or precisely shaped pores and, optionally, macro-channels in a single step, a unitary sheet is preferred.

The hardness and flexibility of polishing layer 10 is predominately controlled by the polyurethane used to fabricate it. The hardness of polishing layer 10 is not particularly limited. The hardness of polishing layer 10 may be greater than about 20 Shore D, greater than about 30 Shore D or even greater than about 40 Shore D. The hardness of polishing layer 10 may be less than about 90 Shore D, less than about 80 Shore D or even less than about 70 Shore D. The hardness of polishing layer 10 may be greater than about 20 Shore A, greater than about 30 Shore A or even greater than about 40 Shore A. The hardness of polishing layer 10 may be less than about 95 Shore A, less than about 80 Shore A or even less than about 70 Shore A. The polishing layer may be flexible. In some embodiments the polishing layer is capable of being bent back upon itself producing a radius of curvature in the bend region of less than about 10 cm, less than about 5 cm, less than about 3 cm, or even less than about 1 cm; and greater than about 0.1 mm, greater than about, 0.5 mm or even greater than about 1 mm. In some embodiments the polishing layer is capable of being bent back upon itself producing a radius of curvature in the bend region of between about 10 cm and about 0.1 mm, between about 5 cm and bout 0.5 mm or even between about 3 cm and about 1 mm.

To improve the useful life of polishing layer 10, it is desirable to utilize polyurethane having a high degree of toughness. This is particularly important, due to the fact the precisely shaped asperities are small in height yet need to perform for a significantly long time to have a long use life. The use life may be determined by the specific process in which the polishing layer is employed. In some embodiments, the use lifetime is at least about 30 minutes at least 60 minutes, at least 100 minutes, at least 200 minutes, at least 500 minutes or even at least 1000 minutes. The use life may be less than 10000 minutes, less than 5000 minutes or even less than 2000 minutes. The useful life time may be determined by measuring a final parameter with respect to the end use process and/or substrate being polished. For example, use life may be determined by having an average removal rate or having a removal rate consistency (as measure by the standard deviation of the removal rate) of the substrate being polished over a specified time period (as defined above) or producing a consistent surface finish on a substrate over a specified time period. In some embodiments, the polishing layer can provide a standard deviation of the removal rate of a substrate being polished that is between about 0.1% and 20%, between about 0.1% and about 15%, between about 0.1% and about 10%, between about 0.1% and about 5% or even between about 0.1% and about 3% over a time period from of, at least about 30 minutes, at least about 60 minutes, at least about 100 minutes at least about 200 minutes or even at least about 500 minutes. The time period may be less than 10000 minutes. To achieve this, it is desirable to use polymeric materials having a high work to failure (also known as Energy to Break Stress), as demonstrated by having a large integrated area under a stress vs. strain curve, as measured via a typical tensile test, e.g., as outlined by ASTM D638. High work to failure may correlate to lower wear materials. In some embodiments, the work to failure is greater than about 3 Joules, greater than about 5 Joules, greater than about 10 Joules, greater than about 15 Joules greater than about 20 Joules, greater than about 25 Joules or even greater than about 30 Joules. The work to failure may be less than about 100 Joules or even less than about 80 Joules.

The polyurethane used to fabricate polishing layer 10 may be used in substantially pure form. The polyurethane materials used to fabricate polishing layer 10 may include fillers known in the art. In some embodiments, the polishing layer 10 is substantially free of any inorganic abrasive material (e.g., inorganic abrasive particles), i.e., it is an abrasive free polishing pad. By substantially free it is meant that the polishing layer 10 includes less than about 10% by volume, less than about 5% by volume, less than about 3% by volume, less than about 1% by volume or even less than about 0.5% by volume inorganic abrasive particles. In some embodiments, the polishing layer 10 contains substantially no inorganic abrasive particles. An abrasive material may be defined as a material having a Mohs hardness greater than the Mohs hardness of the substrate being abraded or polished. An abrasive material may be defined as having a Mohs hardness greater than about 5.0, greater than about 5.5, greater than about 6.0, greater than about 6.5, greater than about 7.0, greater than about 7.5, greater than about 8.0 or even greater than about 9.0. The maximum Mohs hardness is general accepted to be 10. The polishing layer 10 may be fabricated by any techniques known in the art. Micro-replication techniques are disclosed in U.S. Pat. Nos. 6,285,001; 6,372,323; 5,152,917; 5,435,816; 6,852,766; 7,091,255 and U.S. Patent Application Publication No. 2010/0188751, all of which are incorporated by reference in their entirety.

In some embodiments, the polishing layer 10 is formed by the following process. First, a sheet of polycarbonate is laser ablated according to the procedures described in U.S. Pat. No. 6,285,001, forming the positive master tool, i.e., a tool having about the same surface topography as that required for polishing layer 10. The polycarbonate master is then plated with nickel using conventional techniques forming a negative master tool. The nickel negative master tool may then be used in an embossing process, for example, the process described in U.S. Patent Application Publication No. 2010/0188751, to form polishing layer 10. The embossing process may include the extrusion of a polyurethane melt onto the surface of the nickel negative and, with appropriate pressure, the polyurethane melt is forced into the topographical features of the nickel negative. Upon cooling the polyurethane melt, the solid polymer film may be removed from the nickel negative, forming polishing layer 10 with working surface 12 having the desired topographical features, i.e., precisely shaped pores 16 and/or precisely shaped asperities 18 (FIG. 1). If the negative includes the appropriate negative topography that corresponds to a desired pattern of macro-channels, macro-channels may be formed in the polishing layer 10 via the embossing process.

In another embodiment the present description relates to a polishing system, the polishing system includes any one of the previous polishing pads and a polishing solution. The polishing pads may include any of the previous disclosed polishing layers 10. The polishing solutions used are not particularly limited and may be any of those known in the art. The polishing solutions may be aqueous or non-aqueous. An aqueous polishing solution is defined as a polishing solution having a liquid phase (does not include particles, if the polishing solution is a slurry) that is at least 50% by weight water. A non-aqueous solution is defined as a polishing solution having a liquid phase that is less than 50% by weight water. In some embodiments, the polishing solution is a slurry, i.e., a liquid that contains organic or inorganic abrasive particles or combinations thereof. The concentration of organic or inorganic abrasive particles or combination thereof in the polishing solution is not particularly limited. The concentration of organic or inorganic abrasive particles or combinations thereof in the polishing solution may be, greater than about 0.5%, greater than about 1%, greater than about 2%, greater than about 3%, greater than about 4% or even greater than about 5% by weight; may be less than about 30%, less than about 20% less than about 15% or even less than about 10% by weight. In some embodiments, the polishing solution is substantially free of organic or inorganic abrasive particles. By “substantially free of organic or inorganic abrasive particles” it is meant that the polishing solution contains less than about 0.5%, less than about 0.25%, less than about 0.1% or even less than about 0.05% by weight of organic or inorganic abrasive particles. In one embodiment, the polishing solution may contain no organic or inorganic abrasive particles. The polishing system may include polishing solutions, e.g. slurries, used for silicon oxide CMP, including, but not limited to, shallow trench isolation CMP; polishing solutions, e.g. slurries, used for metal CMP, including, but not limited to, tungsten CMP, copper CMP and aluminum CMP; polishing solutions, e.g. slurries, used for barrier CMP, including but not limited to tantalum and tantalum nitride CMP and polishing solutions, e.g. slurries, used for polishing hard substrates, such as, sapphire. The polishing system may further include a substrate to be polished or abraded.

In some embodiments, the polishing pads of the present description may include at least two polishing layers, i.e., a multi-layered arrangement of polishing layers. The polishing layers of a polishing pad having a multi-layered arrangement of polishing layers may include any of the polishing layer embodiments of the present description.

FIG. 3 schematically illustrates an example of a polishing system 100 for utilizing polishing pads and methods in accordance with some embodiments of the present description. As shown, the system 100 may include a polishing pad 150 and a polishing solution 160. The system may further include one or more of the following: a substrate 110 to be polished or abraded, a platen 140 and a carrier assembly 130. An adhesive layer 170 may be used to attach the polishing pad 150 to platen 140 and may be part of the polishing system. Polishing solution 160 may be a layer of solution disposed about a major surface, e.g., working surface, of the polishing pad 150. Polishing pad 150 may be any of the polishing pad embodiments of the present description and includes at least one polishing layer (not shown), as described herein, and may optionally include a subpad and/or foam layer(s), as described for polishing pad 50 and of FIG. 2. The polishing solution is typically disposed on the working surface of the polishing layer of the polishing pad. The polishing solution may also be at the interface between substrate 110 and polishing pad 150. During operation of the polishing system 100, a drive assembly 145 may rotate (arrow A) the platen 140 to move the polishing pad 150 to carry out a polishing operation. The polishing pad 150 and the polishing solution 160 may separately, or in combination, define a polishing environment that mechanically and/or chemically removes material from or polishes a major surface of a substrate 110. To polish the major surface of the substrate 110 with the polishing system 100, the carrier assembly 130 may urge substrate 110 against a polishing surface of the polishing pad 150 in the presence of the polishing solution 160. The platen 140 (and thus the polishing pad 150) and/or the carrier assembly 130 then move relative to one another to translate the substrate 110 across the polishing surface of the polishing pad 150. The carrier assembly 130 may rotate (arrow B) and optionally transverse laterally (arrow C). As a result, the polishing layer of polishing pad 150 removes material from the surface of the substrate 110. In some embodiments, inorganic abrasive material, e.g., inorganic abrasive particles, may be included in the polishing layer to facilitate material removal from the surface of the substrate. In other embodiments, the polishing layer is substantially free of any inorganic abrasive material and the polishing solution may be substantially free of organic or inorganic abrasive particle or may contain organic or inorganic abrasive particles or combination thereof. It is to be appreciated that the polishing system 100 of FIG. 3 is only one example of a polishing system that may be employed in connection with the polishing pads and methods of the present description, and that other conventional polishing systems may be employed without deviating from the scope of the present description.

In another embodiment, the present description relates to a method of polishing a substrate, the method of polishing including: providing a polishing pad according to any one of the previous polishing pads, wherein the polishing pad may include any of the previously described polishing layers; providing a substrate, contacting the working surface of the polishing pad with the substrate surface, moving the polishing pad and the substrate relative to one another while maintaining contact between the working surface of the polishing pad and the substrate surface, wherein polishing is conducted in the presence of a polishing solution. In some embodiments, the polishing solution is a slurry and may include any of the previously discussed slurries. In another embodiment the present description relates to any of the preceding methods of polishing a substrate, wherein the substrate is a semiconductor wafer. The materials comprising the semiconductor wafer surface to be polished, i.e., in contact with the working surface of the polishing pad, may include, but are not limited to, at least one of a dielectric material, an electrically conductive material, a barrier/adhesion material and a cap material. The dielectric material may include at least one of an inorganic dielectric material, e.g., silicone oxide and other glasses, and an organic dielectric material. The metal material may include, but is not limited to, at least one of copper, tungsten, aluminum, silver and the like. The cap material may include, but is not limited to, at least one of silicon carbide and silicon nitride. The barrier/adhesion material may include, but is not limited to, at least one of tantalum and tantalum nitride. The method of polishing may also include a pad conditioning or cleaning step, which may be conducted in-situ, i.e., during polishing. Pad conditioning may use any pad conditioner or brush known in the art, e.g., 3M CMP PAD CONDITIONER BRUSH PB33A, 4.25 in diameter available from the 3M Company, St. Paul, Minnesota. Cleaning may employ a brush, e.g., 3M CMP PAD CONDITIONER BRUSH PB33A, 4.25 in diameter available from the 3M Company, and/or a water or solvent rinse of the polishing pad.

### EXAMPLES

TABLE 1
Materials

| Abbreviation | Description | Source |
|---|---|---|
| Decanol | 1-Decanol | Alfa Aesar, Haverhill, MA |
| Fomrez 44-111 | Poly(butylene adipate) polyol with a hydroxy | Lanxess, Cologne, Germany |
| | number of 111, available under the trade | |
| | designation “FOMREZ 44-111” | |
| 1,4-BDO | 1,4-butanediol | BASF Corporation, |
| | | Ludwigshafen, Germany |
| DBTDL | Dibutyltin dilaurate | PMC Organometallix, Inc, Mount |
| | | Laurel, NJ |
| Rubinate 1234 | MDI-based, low-functionality, polyester-based | Huntsman Corporation, The |
| | prepolymer with 18.9% NCO, available under | Woodlands, TX |
| | the trade designation “RUBINATE 1234” | |
| Chimassorb 944 | Poly[[6-[(1,1,3,3-tetramethylbutyl)amino]- | BASF, Ludwigshafen, Germany. |
| | 1,3,5-triazin-2,4-iyl][(2,2,6,6-tetramethyl-4- | |
| | piperidinyl)imino]-1,6-hexanediyl[(2,2,6,6- | |
| | tetramethyl-4-piperidinyl)imino]]), | |
| | with an M_{N} of 2000-3100 g/mol | |
| 2-Butyl-1- | 2-butyl-1-n-octanol | TCI America, Portland, OR |
| Octanol | | |

### Test Methods

### General Microcompounder Polymerization Method

Thermoplastic polyurethanes were prepared using an MC15 Micro Compounder (obtained from Xplore Instruments, Sittard, The Netherlands). Polyol, chain extender, isocyanate, and amine (per the compositions shown in Tables 2 and 3) were added to the microcompounder with a total charge of 15 mL. The reactive mixture was mixed for five minutes with a screw speed of 100 RPM and a temperature setting of 210° C. to allow polymerization to occur. The resulting polymer was then pressed into a flat sheet using a hydraulic press at 375° F.

### Melt Viscosity Measurement

The melt viscosity was measured using a DHR-2 rheometer (TA Instruments, New Castle, DE). A disk of polymer between 1.0 and 2.0 mm thick having a diameter for 8 mm was dried in a 100° C. oven and stored in a vial with desiccant. The sample was mounted in the rheometer with 8 mm diameter parallel plates. The sample was tested using a temperature ramp from 150° C. to 240° C. with oscillations of 1% strain and angular frequency of 1.0 rad/s. The complex viscosity measured at 200° C. is reported.

### Examples 1 to 8

Examples 1 to 8 were prepared using the General Microcompounder Polymerization Method according to the compositions of Table 2. The viscosities of the resulting materials are also displayed in Table 2. These examples show that the melt viscosity of the resin is controlled by the decanol content and the melt viscosity is relatively insensitive to changes in isocyanate index between 0.996 and 1.029.

TABLE 2
Composition of Reactive Mixtures (values in wt. %)

| Component | Ex. 1 | Ex. 2 | Ex. 3 | Ex. 4 | Ex. 5 | Ex. 6 | Ex. 7 | Ex. 8 |
|---|---|---|---|---|---|---|---|---|
| Fomrez 44-111 | 33.39 | 33.77 | 33.77 | 34.04 | 33.97 | 33.84 | 33.97 | 34.04 |
| 1,4-Butanediol | 7.26 | 7.29 | 7.22 | 7.36 | 7.22 | 7.12 | 7.22 | 7.24 |
| Rubinate 1234 | 52.85 | 52.78 | 52.96 | 52.64 | 52.88 | 53.07 | 52.85 | 52.90 |
| DBTDL | 0.005 | 0.005 | 0.005 | 0.005 | 0.005 | 0.005 | 0.005 | 0.005 |
| Chimassorb 944 | 5.50 | 5.50 | 5.48 | 5.49 | 5.47 | 5.51 | 5.49 | 5.49 |
| Decanol | 1.00 | 0.66 | 0.56 | 0.45 | 0.45 | 0.45 | 0.46 | 0.33 |
| Isocyanate Index | 1.001 | 1.003 | 1.015 | 0.996 | 1.015 | 1.029 | 1.014 | 1.016 |
| Viscosity at 200° | 867 | 1978 | 2286 | 4679 | 5500 | 3756 | 4243 | 6922 |
| C. (Pa s) | | | | | | | | |

### Comparative Example 9

Poly THF650 (4.60 g, 0.0142 equiv.), Chimassorb 944 (10.62 g, 0.0071 equiv.), and 4.4-MDI (1.77 g, 0.0142 equiv.) were added to an MC15 Micro Compounder. In this formulation, there are 0.0071 more equivalents of hydroxyl groups and amine end groups than isocyanate groups, so the resulting polymer is expected to have an end group concentration of 0.47 mol/kg, with the end groups being hydroxyl groups or amine groups. This reactive mixture was processed in the microcompounder at 150° C. and 100 RPM screw speed. After 1.5 minutes a portion of the material was collected. FTIR analysis of this sample showed no remaining isocyanate peak. After a total of 5 minutes reaction time, another portion of the material was collected. After 15 minutes of reaction time, the remaining material was collected. The three samples were dissolved in CDCl₃. The 1H proton spectra were taken with a 500 MHz NMR acquired with a low tip angle (15 degrees) and a relaxation delay of 4 seconds (AVANCE III 500 MHz spectrometer equipped with a broadband cryoprobe from Bruker, Billerica, MA). In the resulting spectra, the peak at 3.65 ppm was assigned to the methylene group alpha to a hydroxyl end group that had not reacted with isocyanate. The peak at 2.65 ppm was assigned to the methylene group alpha to the amine endgroups of Chimassorb 944 that had not reacted with isocyanate. The peak at 4.16 ppm was assigned to methylene groups alpha to carbamate groups formed by the reaction of PolyTHF 650 with MDI. The integrations of these characteristic peaks were used to calculate the concentration of unreacted hydroxyl groups, unreacted amine end groups, and carbamate groups at each time point. The results in Table 3 show that during the course of the reaction, the hydroxyl group concentration decreased by 0.094 mol/kg while the amine concentration increased by 0.064 mol/kg and the carbamate concentration increased by 0.075 mol/kg. This is consistent with the shift of from a kinetically favored product of urea groups and excess hydroxyl end groups towards a more thermally stable product of urethane groups and excess amine end groups.

### Example 10

PolyTHF650 (2.34 g, 0.0072 equiv.), Chimassorb 944 (10.81 g, 0.0072 equiv.), Decanol (1.14 g, 0.0072 equiv.) and 4.4′-MDI (2.71 g. 0.0216 equiv.) were added to an MC15 Micro Compounder In this case, there are equal number of isocyanate equivalents and equivalents of hydroxyl groups and reactive amine groups. Therefore, the resulting polymer is expected to have only decanol-capped end groups, and the concentration of the end groups is expected to be 0.48 mol/kg, which is similar to end group concentration in Comparative Example 9. This reactive mixture was subjected to the same method used with Comparative Example 9, and the resulting concentrations of hydroxyl end groups, amine end groups, and carbamate at each time point are shown in Table 3. During the course of the reaction, the concentrations of hydroxyl end group, amine end group, and carbamate end group all remained relatively unchanged (decreases of 0.008 mol/kg, 0.010 mol/kg, and 0.013 mol/kg, respectively), showing that the polymer structure with Example 10 is chemically more stable than the polymer structure of Comparative Example 9.

TABLE 3
Concentrations of Functional Groups
as a Function of Processing Time

| | | Hydroxyl | Amine | |
|---|---|---|---|---|
| | Reaction | endgroup | endgroup | Carbamate |
| | time | conc. | conc. | conc. |
| | (min) | Mol/kg | Mol/kg | Mol/kg |
| Comp. | 1.5 | 0.340 | 0.125 | 0.530 |
| Ex. 9 | 5 | 0.284 | 0.149 | 0.550 |
| | 15 | 0.246 | 0.189 | 0.605 |
| Ex. 10 | 1.5 | 0.029 | 0.020 | 0.792 |
| | 5 | 0.023 | 0.012 | 0.790 |
| | 15 | 0.021 | 0.010 | 0.779 |

### Reactive Extrusion Method for Examples 11 and Comparative Example 12

Examples 11 and 12 (Comparative) were prepared using conventional reactive extrusion techniques. A twin-screw extruder, Model ZE40A, available from Berstorff Corp., Florence KY, having 7 barrel sections with each barrel having a 5 cm diameter was used to prepare the polyurethanes according to the formulations shown in Table 4. In the discussion that follows, the first barrel was closest to the extruder drive mechanism and seventh barrel was nearest the exit of the extruder. Fomrez 44-111 was added to the first barrel section via a heated ZENITH B-9000 gear pump, available from Circor International, Inc., Burlington, MA. 1,4-butanediol was added to the first section barrel via a second ZENITH B-9000 gear pump. DBTL was also added to the first barrel section via a PHD ULTRA HPSI/XF syringe pump, available from Harvard Apparatus, Holliston, MA. Decanol was added into the first section barrel and metered with a Tuthill D-Series Gear Pump, available from Ingersoll Rand, Inc. Rubinate 1234 was added to the second barrel section via a third ZEITH B-9000 gear pump. Chimassorb 944 was metered into a side stuffer unit via a Ktron loss in weight feeder, available from Coperion, Pittman. NJ. The side stuffer conveyed the Chimassorb 944 into barrel section 4. The molten polyurethane discharged from the extruder into a ZENITH PEP II gear pump, available from Circor International, Inc, operating at about 20 cm3/min. The polyurethane was pumped into an underwater pelletizer, model number EUP10, available from ECON Inc. Monroe, MI. The polyurethanes were prepared at a rate of about 100 lb/hr (45 kg/hr).

TABLE 4
Composition of Reactive Mixtures (values in wt. %)

| Component | Ex. 11 | Comp. Ex. 12 |
|---|---|---|
| Fomrez 44-111 | 34.07 | 34.4 |
| 1,4-Butanediol | 7.24 | 7.2 |
| Rubinate 1234 | 52.85 | 52.9 |
| DBTDL | 0.02 | 0.005 |
| Chimassorb 944 | 5.50 | 5.5 |
| Decanol | 0.35 | |
| Isocyanate Index | 1.015 | 1.02 |
| Viscosity at 200° C. (Pa s) | 9578 | 32650 |

### Example 13

Example 13 was prepared using the General Microcompounder Polymerization Method according to the composition of Fomrez 44-111 (33.9 wt %), 1,4-BDO (7.2 wt %), Rubinate 1234 (52.9 wt %), DBTDL (0.005 wt %), Chimassorb 944 (5.5 wt %) and 2-Butyl-1-Octanol (0.53 wt %). The viscosity of the resulting material at 200° C. was 2723 Pa s.

Various modifications and alterations of this invention will become apparent to those skilled in the art without departing from the scope and spirit of this invention.

What is claimed is:

1. A polyurethane comprising a reaction product of a reactive mixture including.
a polyol;
a diol chain extender;
a diisocyanate;
a mono-alcohol; and
a multifunctional amine according to at least one of Formula I and Formula II 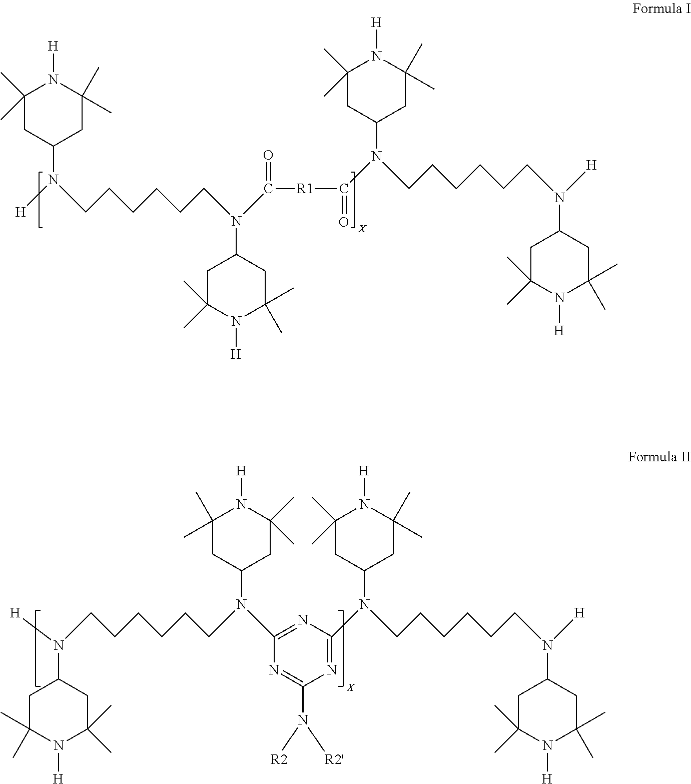
wherein,
X is an integer from 0 to 10, inclusive of the endpoints,
R1 is a linear or branched aliphatic group, cyclic aliphatic group, aromatic group or a compound containing an aromatic group having from 2 to 20 carbon atoms,
R2 is a linear or branched alkyl group having from 1 to 20 carbon atoms,
R2′ is hydrogen or a linear or branched alkyl group having from 1 to 20 carbon atoms; and
wherein the mole ratio of isocyanate groups to hydroxyl groups in the reactive mixture is 0.98 or greater.

2. The polyurethane of claim 1, wherein the mono-alcohol is a fatty alcohol.

3. The polyurethane of claim 2, wherein the fatty alcohol is a C6-C12 fatty alcohol.

4. The polyurethane of claim 2, wherein the fatty alcohol is 1-decanol.

5. A polishing pad comprising a polishing layer having a working surface and a second surface opposite the working surface, wherein the polishing layer includes the polyurethane of claim 1.

6. The polishing pad of claim 5, wherein the polishing layer includes more than 90% by weight of the polyurethane of claim 1.

7. The polishing pad of claim 5, wherein the working surface includes a land region and at least one of a plurality of precisely shaped pores and a plurality of precisely shaped asperities.

8. The polishing pad of claim 5, wherein the polishing layer further comprises a plurality of independent or inter-connected macro-channels.

9. The polishing pad of claim 5, further comprising a subpad, wherein the subpad is adjacent to the second surface of the polishing layer.

10. The polishing pad of claim 5, wherein the polishing layer includes less than 1% by volume inorganic abrasive particles.

11. A polishing system comprising the polishing pad of claim 5 and a polishing solution.

12. The polishing system of claim 11, wherein the polishing solution is a slurry.

13. A method of polishing a substrate, the method comprising:
providing a polishing pad according to claim 5;
providing a substrate;
contacting the working surface of the polishing layer with the substrate surface;
moving the polishing pad and the substrate relative to one another while maintaining contact between the working surface of the polishing pad and the substrate surface, wherein polishing is conducted in the presence of a polishing solution.

14. The method of polishing a substrate of claim 13, wherein the polishing solution is a slurry.

15. The method of polishing a substrate of claim 13, wherein the substrate is a semiconductor wafer.
